(19) United States
(12) Patent Application Publication
(10) Pub. No.: US 2011/0013685 A1
(43) Pub. Date: Jan. 20, 2011

(54) Channel and Equalization Coefficient Based Timing Recovery

(75) Inventor: Russell C. McKown, Richardson, TX (US)

Correspondence Address: RG & ASSOCIATES, 1103 TWIN CREEKS, STE. 120, ALLEN, TX, 75013, US

(73) Assignee: ADVANCED RECEIVER TECHNOLOGIES, LLC, Dallas, TX (US)

(21) Appl. No.: 12/502,283

(22) Filed: Jul. 14, 2009

(51) Int. Cl. H03H 7/30; H04L 7/00

(52) U.S. Cl. 375/232; 375/233; 375/354

(57) ABSTRACT

A module and method for channel estimate and equalization coefficient based timing recovery comprises a timing estimation module, two channel estimation modules communicably coupled to the timing estimation module, an equalization coefficient computation module communicably coupled to the timing estimation module and one of the channel estimation modules, a conversion module communicably coupled to the timing estimation module and to the two channel estimation modules, and a pulse shaping filter communicably coupled to the conversion module, wherein: the pulse shaping filter receives a signal and outputs a filtered signal, the conversion module receives the filtered signal and outputs two 1/T rate signal streams, a sample time=t stream and a sample time=t−Ω stream where Ω is small compared to T, with each stream going to one of the two channel estimation modules, the channel estimation modules each output a 1/T Channel Impulse Response (CIR) estimate to the timing estimation module, the equalization coefficient computation module receives the CIR estimate from the channel estimation module that receives the sample time=t signal stream and outputs the equalization coefficients to the timing estimation module, and the timing estimation module outputs a timing offset parameter to the conversion module, wherein the timing offset parameter is used in conjunction with the output of the pulse shaping filter to provide two 1/T rate signal streams.

### CROSS-REFERENCE TO RELATED APPLICATIONS

The present patent application is related to U.S. Provisional Patent Application 60/628,248 filed on Nov. 16, 2004, entitled Chip-Level No-Decision Feedback Equalizer For CDMA Wireless Systems, U.S. patent application Ser. No. 11/280,858 filed on Nov. 16, 2005, entitled Chip-Level No-Decision Feedback Equalizer For CDMA Wireless Systems, and U.S. patent application Ser. No. 10/796,596 filed on Mar. 9, 2004, entitled Methods and Apparatus For Single Burst Equalization of Single Carrier Signals In Broadband Wireless Access Systems now issued U.S. Pat. No. 7,388,910 and U.S. patent application Ser. No. 11/900,343 filed on Sep. 11, 2007 entitled Efficient Channel Estimate Based Timing Recovery and U.S. patent application Ser. No. 12/157,738 entitled Method and Apparatus for Single Burst Equalization of Singe Carrier Signals in Broadband Wireless Access Systems and U.S. patent application Ser. No. 12/079,397 filed on Mar. 26, 2008 entitled Active Spread Code Detection and U.S. patent application Ser. No. 12/323,520 filed on Nov. 26, 2008 entitled Efficient Despread and Respread of Muli-Rate CDMA Signals, the contents of each of which are incorporated by reference herein.

### BACKGROUND OF INVENTION

In current telecommunication systems, digital information of interest is typically communicated from a transmitter at one location to a receiver at another location by first forming a sequence of symbols based on the digital information and then using the symbol sequence to modulate a single carrier signal or a multiple carrier signal. At the receiver, the carrier signal is removed and the resultant, so called, ‘baseband’ signal is processed to recover first the symbols and then the digital information of interest. In general, signals used to communicate digital information from a transmitter to a receiver can be referred to as digital communication signals. Although the details of the mapping of the digital information onto the symbols vary from one application to another as do the details of the signal modulation, it is standard practice in the design of digital communication signals to use a fixed symbol rate (or a well defined set of fixed symbol rates) such that the individual symbols are used to modulate the signal for a fixed interval of time. The inverse of this individual symbol time interval is referred to as the symbol rate.

It is also standard practice in the design of digital communication signals to place what is referred to as a pulse shaping filter in the transmitter-to-receiver channel response or equivalently, the transmitter-to-receiver transfer function. The pulse shaping filter imposes a shape to the individual symbol ‘pulses’ so as to minimize the interference between the symbol pulses at the communications signal receiver. By far the most common example of a pulse shaping filter is the raised cosine filter (RCF). Typically the RCF is distributed between the transmitter and the receiver such that a root raised cosine filter (RRCF) is at both the transmitter and the receiver, the net contribution to the transmitter-to-receiver channel response being equivalent to one RCF.

An example of such a telecommunication signal is the third generation (3G) Wideband Code Division Multiple Access (WCDMA) signal specified by the Third Generation Partnership Project (3GPP) standards organization. For the WCDMA signal, and code division multiple access signals in general, the fundamental timing interval is the chip rate whereas the symbol rates are well defined multiples of the chip rate.

It is also standard practice in the design of digital communication receivers for these digital communication signals to provide a channel equalization filter to mitigate the effects of multiple path (or multipath) propagation channels that otherwise result in inter-symbol distortions and, subsequently, increased symbol error rates.

Symbol (chip) timing recovery refers to the process in the communications signal receiver that estimates the time when the information and/or energy associated with individual symbols (chips) arrives in the received communications signal. The transmitter typically clocks the symbol (chip) interval based on a crystal oscillator and, in order to be accurate, the timing recovery process at the receiver must be capable of dynamically tracking changes in the fundamental timing interval that are due to variations in the transmitter's crystal oscillator frequency.

If the communications signal receiver is battery operated it is desirable to process the communications signal at a low sample rate in order to reduce the computations per symbol (digital information unit of interest). Fewer computations per symbol result in lower power consumption by the receiver and extend the battery life. This is especially desirable for today's mobile broadband communication devices, examples being 3G mobile phones and battery operated computers with embedded wireless broadband network interfaces.

Symbol timing recovery for the above described digital communications signals is an important function. For example, for CDMA signals accurate symbol timing is critical for computationally efficient, digital equalization filters which operate on multipath channel distorted signal data that has been sampled at the minimum rate of 1 sample per chip. Prior art timing algorithms for a multipath channel and an equalization filter have a problem in that they require the estimation of multiple coefficients from either the channel estimate or the equalization filter. For this reason they are not robust for deep fading multipath propagation channels. During signal fades, the estimate of the CIR is often reduced to a single coefficient and, at the same time, only a single coefficient of the equalization filter is reliable, the coefficient at the filter's cursor position. As such, what is needed is a system and method for timing recovery that overcomes this limitation.

### SUMMARY OF INVENTION

The present invention provides a system (or module) and method of a timing recovery for digital communications signals that have been distorted by a multipath channel and are processed by an equalization filter to compensate that distortion. The invention allows the associated signal processing to be performed at a minimum rate of one sample per fundamental timing interval T and applies to a transmitter-to-receiver channel that includes a pulse shaping filter that can be characterized by a pulse width parameter which is equal to T. Timing recovery is accomplished by: 1) creating two sampled signal streams such that each stream is sampled at the minimum 1/T rate while maintaining a small time difference, Ω, between the sample times associated with corresponding elements of the two signal streams; 2) producing two minimal 1/T resolution CIR estimate waveforms, one for each of the two 1/T sample rate signal streams; 3) computing coefficients for a 1/T sample rate equalization filter from one of the 1/T resolution channel estimate waveforms; and 4) applying a timing estimation procedure which uses the largest coefficient of each of the two CIR estimates and the largest coefficient of the equalization filter.

### BRIEF DESCRIPTION OF THE DRAWINGS

FIG. 1 depicts a block diagram of an example implementation of an analog input timing and equalization coefficient module within a receiver for a communication signal in accordance to an embodiment of the present invention;

FIG. 2 depicts a block diagram of an example implementation of multiple analog input timing and equalization coefficient modules within a receiver for multiple communication signals in accordance to an embodiment of the present invention;

FIG. 3 depicts a block diagram of an example implementation of a digital input timing and equalization coefficient module within a receiver for a communication signal in accordance to an embodiment of the present invention;

FIG. 4 depicts a block diagram of an example implementation of multiple digital input timing and equalization coefficient modules within a receiver for multiple communication signals in accordance to an embodiment of the present invention;

FIG. 5 depicts a block diagram of an example implementation of an analog input timing and equalization coefficient module within a receiver for a communication signal in accordance to an embodiment of the present invention;

FIG. 6 depicts a block diagram of an example implementation of an digital input timing and equalization coefficient module within a receiver for a communication signal in accordance to an embodiment of the present invention;

FIG. 7 shows a block diagram of certain processes performed by an implementation of a timing estimation module in accordance to an embodiment of the present invention; and

FIG. 8 shows a block diagram of certain processes performed by an implementation of a timing offset determination module in accordance to an embodiment of the present invention.

### DETAILED DESCRIPTION OF THE INVENTION

The present invention provides a system (or module) and method of a timing recovery for digital communication signals that have been distorted by a multipath channel and are processed by an equalization filter to compensate that distortion. The invention allows the associated signal processing to be performed at a minimum 1/T rate that equals one sample per fundamental timing interval T. The present invention can be utilized with any wireless signal that utilizes a fixed timing interval which includes Code Division Multiple Access (CDMA), Orthogonal Frequency Division Multiple Access (OFDMA), and Orthogonal Frequency Division Multiplexing (OFDM).

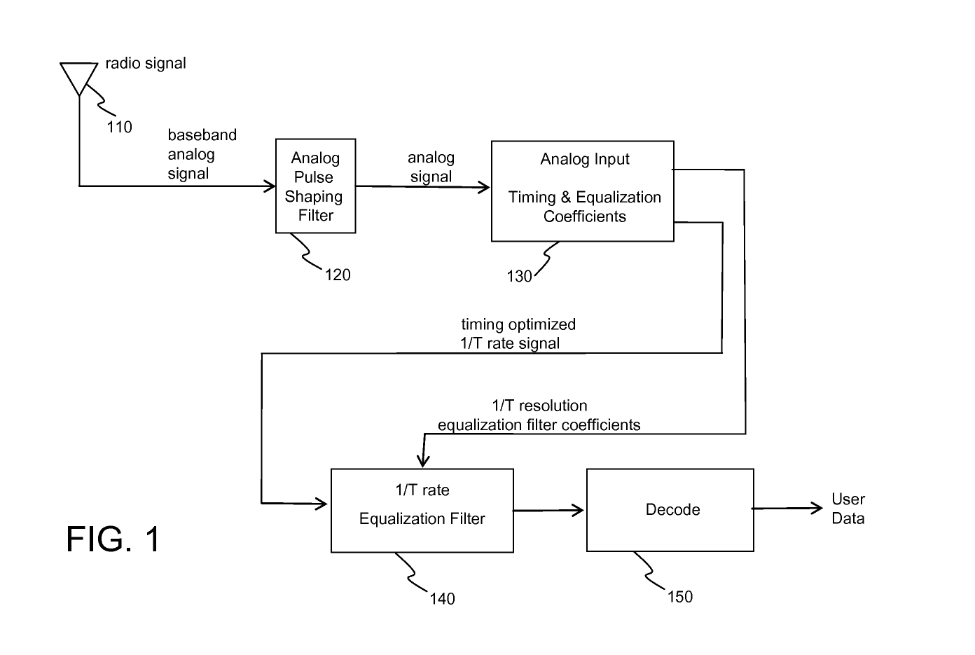

FIG. 1 shows a block diagram of certain processes performed by an implementation of a receiver that contains the channel estimate and equalization coefficient based timing recovery system. In the process configuration of FIG. 1, a radio frequency signal is received with a single antenna 110 and frequency down-converted to an in-phase and quadrature (I&Q) baseband signal. An analog pulse shaping filter 120 receives the I&Q baseband analog input signal and outputs a filtered I&Q analog signal that is received by the analog input timing and equalization coefficient module 130 of the present invention. (Note that I&Q notation of the in-phase and quadrature signals is omitted in the rest of this specification.) The timing and equalization coefficient module 130 provides timing optimized 1/T rate sampled signal data and 1/T resolution equalization coefficients to equalization filter 140 which filters the signal to compensate for multipath channel distortions. The output of equalization filter 140 is processed by a decode module 150 to provide the user data of interest, for example, to a 3G WCDMA network subscriber.

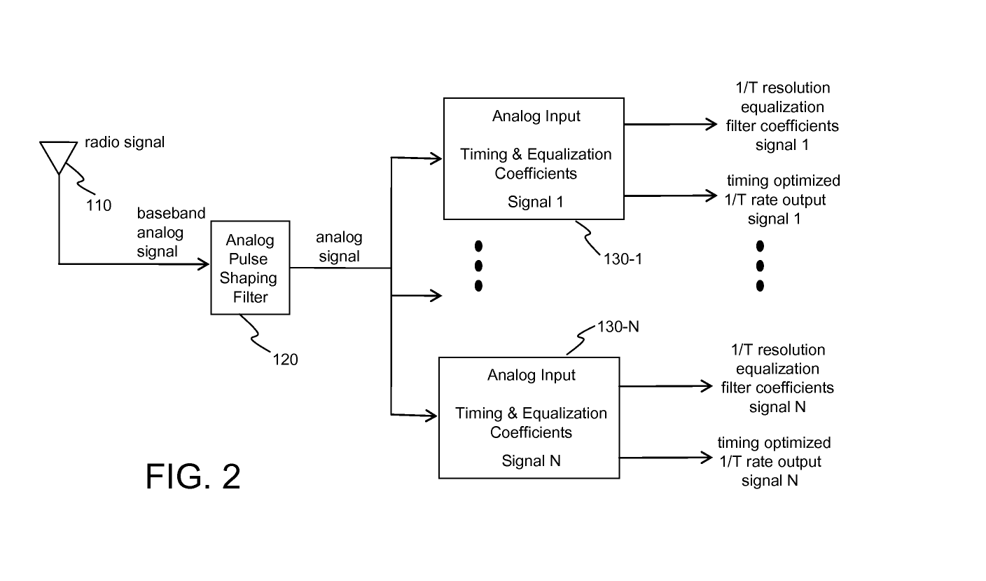

FIG. 2 shows a block diagram of certain processes performed by an implementation that extends the receiver of FIG. 1 to N signals. In this N signal implementation, the analog pulse shaping filter 120 receives the baseband analog input signal and outputs a filtered analog signal that is received by N analog input timing and equalization coefficient modules 130-1 to 130-N of the present invention. The associated N equalization filters and N decode modules are not shown in FIG. 2.

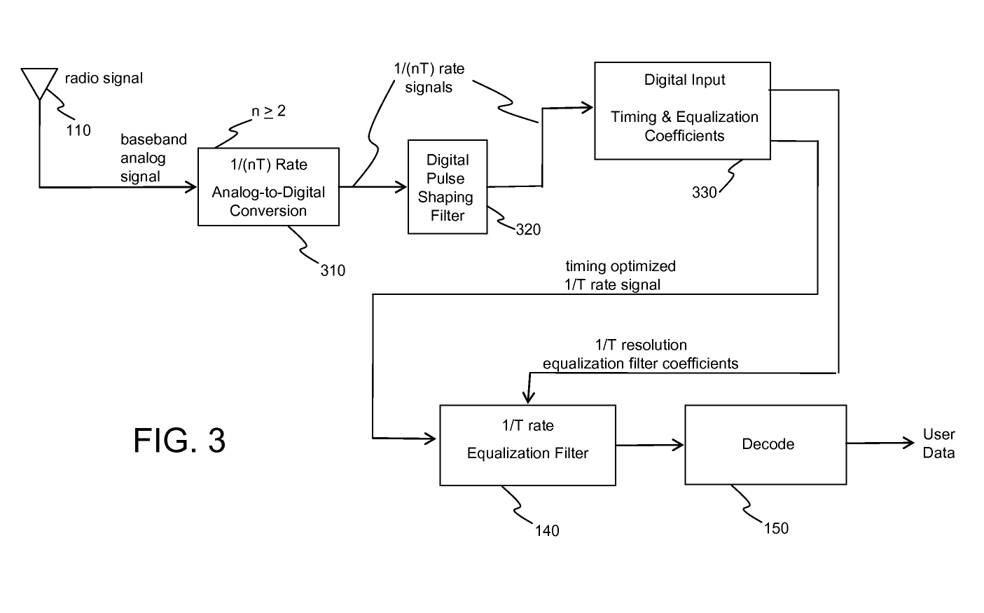

FIG. 3 shows a block diagram of certain processes performed by an alternative implementation of a receiver that contains the channel estimate and equalization coefficient based timing recovery system. In the process configuration of FIG. 3, analog-to-digital conversion module 310 receives the baseband analog input signal and converts it to a digital 1/(nT) rate sampled signal where T is the signal's nominal fundamental timing interval, for example, for a CDMA signal T is the chip interval. The oversampling factor n is greater than or equal to 2. The 1/(nT) rate signal is filtered by a digital pulse shaping filter 320 and provided to a digital input timing and equalization coefficient module 330 of the present invention. The timing and equalization coefficient module 330 provides timing optimized 1/T rate sampled signal data and 1/T resolution equalization coefficients to equalization filter 140 which filters the signal to compensate for multipath channel distortions. The output of equalization filter 140 is processed by a decode module 150 to provide the user data of interest.

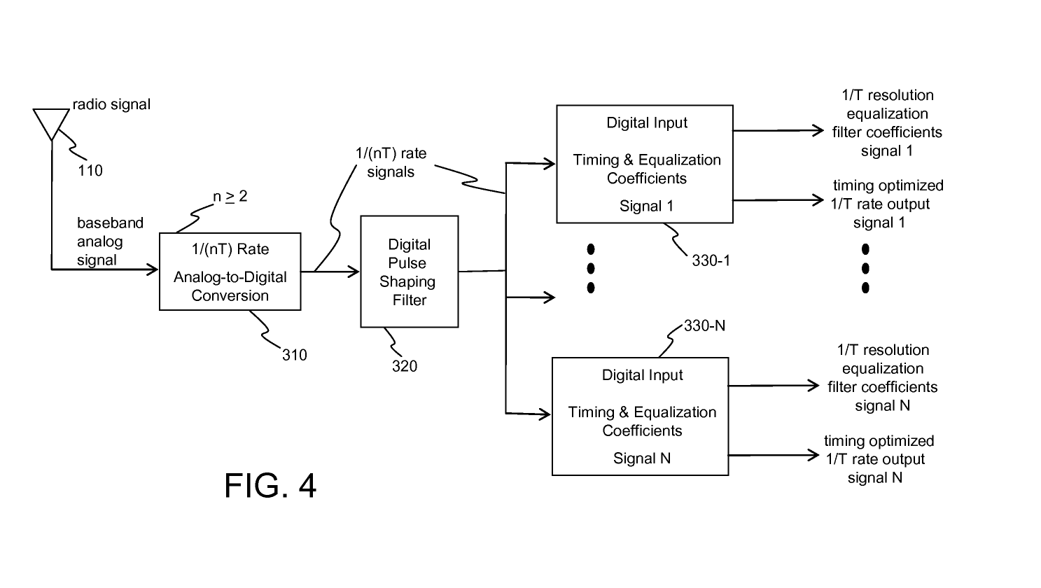

FIG. 4 shows a block diagram of certain processes performed by an implementation that extends the receiver of FIG. 3 to N signals. In this N signal implementation, the digital pulse shaping filter 320 provides 1/(nT) rate signal to N digital input timing and equalization coefficient modules 330-1 to 330-N of the present invention. The associated N equalization filters and N decode modules are not shown in FIG. 4.

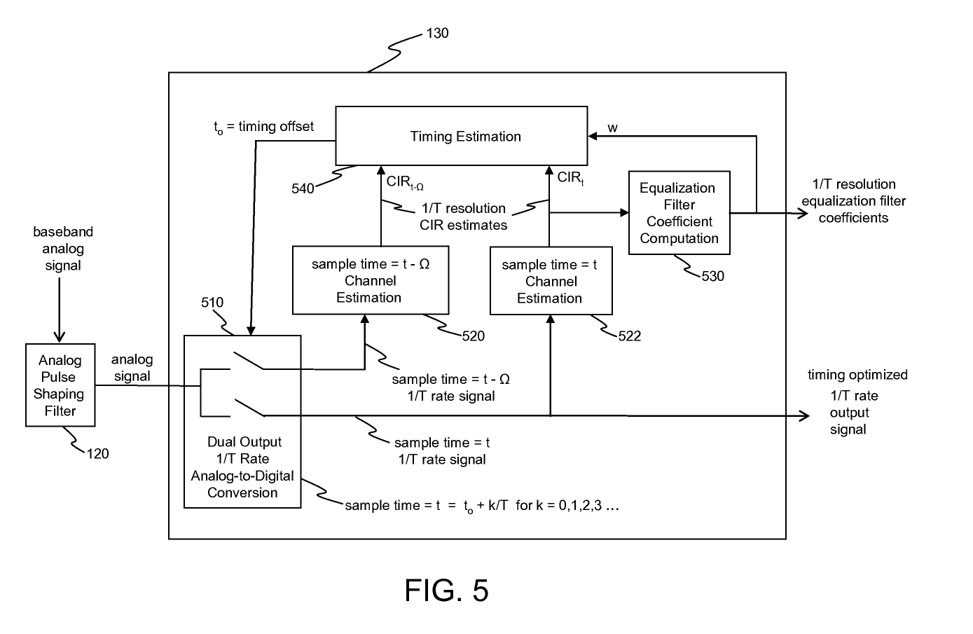

FIG. 5 shows a block diagram of certain processes performed by an implementation of the analog input timing and equalization coefficient module 130 of the present invention. The pulse shape filtered analog signal is input to a dual output 1/T rate analog-to-digital conversion module 510 which also inputs timing offset control parameter to. The dual output 1/T rate analog-to-digital conversion module 510 outputs two streams of 1/T rate sampled signal data, a sample time=t stream and a delayed sample time=t−Ω stream, where t=tₒ+k/T for k=0,1,2,3 . . . and Ω is small compared to T. The 1/T rate, sample time=t signal stream is input to channel estimation module 522 and the 1/T rate, sample time=t−Ω signal stream is input to channel estimation module 520. The 1/T rate, sample time=t signal stream from the dual output 1/T rate analog-to-digital conversion module 510 is also output from the analog input timing and equalization coefficient module 130.

Channel estimation modules 520 and 522 each provide a 1/T resolution CIR estimate, CIR_{t-Ω} and CIRₜ, respectively, to the timing estimation module 540. The 1/T resolution of these CIR estimates corresponds to a unit time lag being equal to T. In general, these two complex valued CIR estimates will differ slightly due the sampling delay Ω. The 1/T resolution CIRₜ estimate that is output from channel estimation module 522 is also received by the equalization filter coefficient computation module 530 which determines coefficients w for a 1/T rate equalization filter based on the CIR estimate. These 1/T resolution equalization filter coefficients w are provided to the timing estimation module 540 in addition to being output from the analog input timing and equalization coefficient module 130.

Timing estimation module 540 receives the 1/T resolution CIR estimates, CIR_{t-Ω} and CIRₜ, from channel estimation modules 520 and 522 and the 1/T resolution equalization filter coefficients w from equalization filter coefficient computation module 530 and determines the timing offset control parameter tₒ which is provided as output. The timing offset control parameter to is received by the dual output 1/T rate analog-to-digital conversion module 510 as described above.

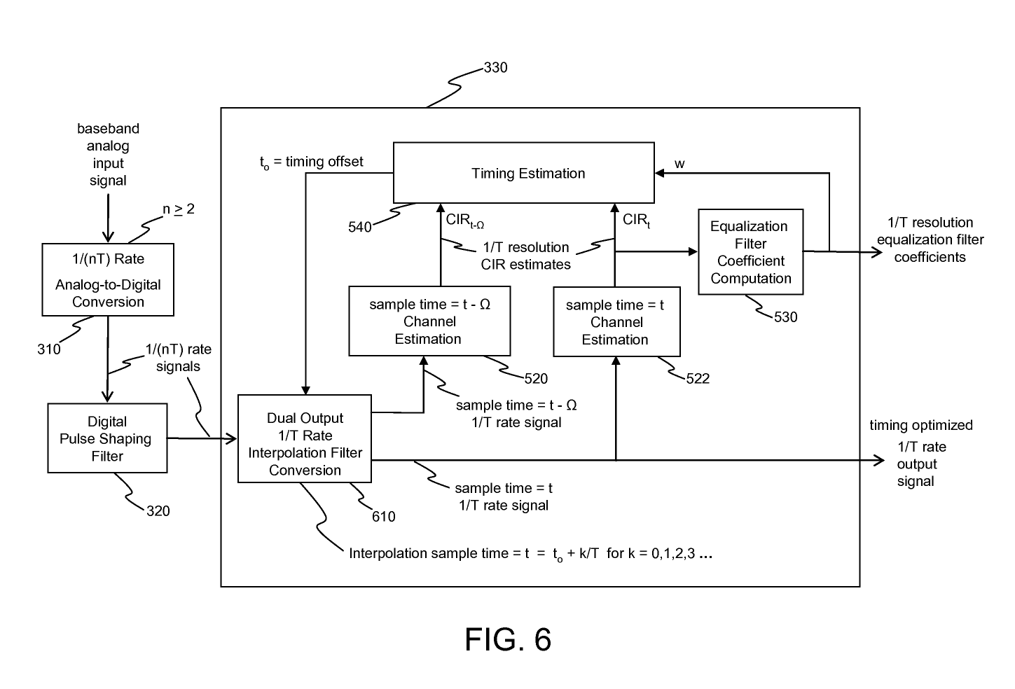

FIG. 6 shows a block diagram of certain processes performed by an implementation of the digital input timing and equalization coefficient module 330 of the present invention. The pulse shape filtered 1/(nT) rate digital signal is input to a dual output 1/T rate interpolation filter conversion module 610 which also inputs timing offset control parameter tₒ. The dual output 1/T rate interpolation filter conversion module 610 outputs two streams of 1/T rate sampled signal data, a sample time=t stream and a delayed sample time=t−Ω stream, where t=tₒ+k/T for k=0,1,2,3 . . . and Ω is small compared to T. A preferred embodiment is to set Ω=1/(nT) which typically simplifies the design of the dual output 1/T rate interpolation filter conversion module 610. The 1/T rate, sample time=t signal stream is input to channel estimation module 522 and the 1/T rate, sample time=t−Ω signal stream is input to channel estimation module 520. The 1/T rate, sample time=t signal stream from the dual output 1/T rate interpolation filter conversion module 610 is also output from the analog input timing and equalization coefficient module 330. The channel estimation modules 520 and 522, the equalization filter coefficient computation module 530 and the timing estimation module 540 in FIG. 6 are the same as described above for FIG. 5.

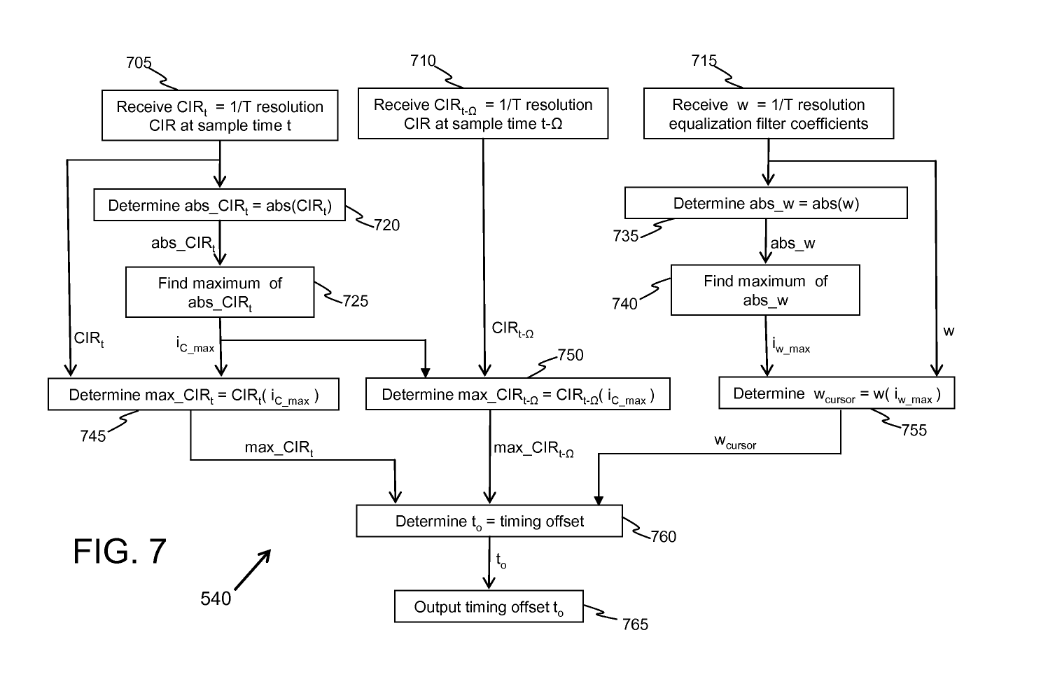

FIG. 7 shows block diagrams of certain processes performed by an implementation of the timing estimation module 540 of the present invention. The timing estimation module 540 receives the 1/T resolution channel estimate CIRₜ and CIR_{t-Ω}, 705 and 710, and equalization filter coefficient vector, w, 715. The vector abs_CIRₜ is determined as the absolute value of the channel estimate vector CIRₜ in absolute value module 720 and the vector abs_w is determined as the absolute value of the equalization filter coefficient vector w in absolute value module 735. The maximums of the absolute value vectors abs_CIRₜ and abs_w are determined in maximum modules 725 and 740 which output the indices of the maximum as i_{C}_{_{—}}ₘₐₓ and i_{w}_{_{—}}ₘₐₓ, respectively. Indexed coefficient selection modules 745 and 750 receive i_{C}_{_{—}}ₘₐₓ and also receive CIRₜ and CIR_{t-Ω}, respectively, which they use to set complex scalar coefficients

max_CIRₜ=CIRₜ(i_{C}_{_{—}}ₘₐₓ) and

max_CIR_{t-Ω}=CIR_{t-Ω}(i_{C}_{_{—}}ₘₐₓ)

that are associated with the maximum magnitude coefficient of CIRₜ and CIR_{t-Ω}, respectively. Indexed coefficient selection module 755 receives i_{w}_{_{—}}ₘₐₓ and w and sets w_{cursor}=w(i_{w}_{_{—}}ₘₐₓ). Timing offset determination module 760 receives the three complex coefficients, max_CIRₜ, max_CIR_{t-Ω} and w_{cursor}, and determines a timing offset control parameter tₒ which is output 765 from the timing estimation module 540.

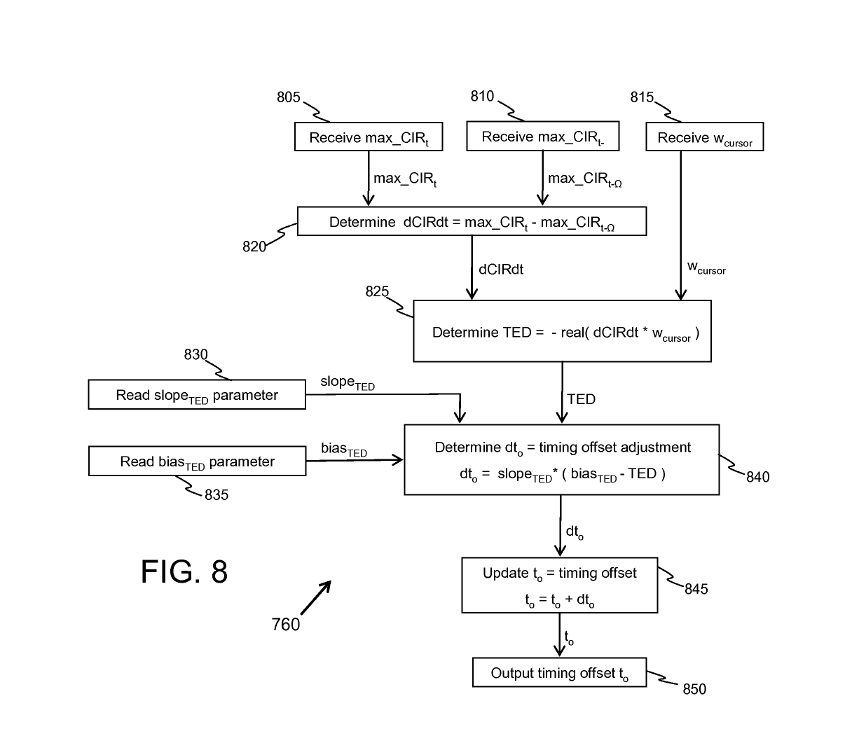

FIG. 8 shows block diagrams of certain processes performed by an implementation of the timing offset determination module 760 of the present invention. A complex scalar difference module 820 in FIG. 8 receives max_CIRₜ and max_CIR_{t-Ω} and determines

dCIRdt=max_CIRₜ−max_CIR_{t-Ω}.

The above dCIRdt is a derivative of the 1/T resolution channel estimate with respect to the sample time evaluated at the time lag i_{C}_{_{—}}ₘₐₓ where i_{C}_{_{—}}ₘₐₓ identifies the maximum absolute value of the channel estimate CIRₜ. Note that due to the fact Ω is small compared to T, i_{C}_{_{—}}ₘₐₓ also identifies the maximum absolute value of the channel estimate CIR_{t-Ω} that is derived from the delayed 1/T data stream.

A timing error detection module 825 in FIG. 8 receives the complex scalars dCIRdt and w_{cursor} and determines the value of a timing error detector TED as a real scalar

TED=−real(dCIRdt*w_{cursor})

Note that the above TED is robust with respect to signal fades because it is determined from only the largest magnitude coefficients of CIRₜ, CIR_{t-Ω} and w.

Parameter read modules 830 and 835 in FIG. 8 read real scalar parameters slope_{TED} and bias_{TED} from memory or some other source. A timing offset adjustment module 840 receives these slope and bias parameters as well as the determined TED and determines a timing offset adjustment

dtₒ=slope_{TED}*(bias_{TED}−TED).

The above timing offset adjustment dtₒ is received by a timing offset update module 845 which accumulates dtₒ into to as

tₒ=tₒ+dtₒ.

This updated timing offset tₒ is then output 850 from the timing offset determination module 760.

As indicated in FIG. 5 for the analog input timing and equalization coefficient module 130 and in FIG. 6 for the digital input timing and equalization coefficient module 330, the updated timing offset tₒ is applied to the conversion module that provides the two 1/T rate sampled data streams. The conversion modules that receive to are the dual output 1/T rate analog-to-digital conversion module 510 in FIG. 5 and the dual output 1/T rate interpolation filter conversion module 610 in FIG. 6. In either case a closed loop is created in which the sample times are adjusted in a manner that allows the TED value to approach the bias_{TED} parameter. Standard control loop parameter adjustment procedures can be followed to set the slope_{TED} parameter such that this timing recovery loop has reasonable acquisition and tracking properties. Provided the bias_{TED} is properly chosen, this method of channel estimate and equalization coefficient based timing recovery can provide the desired timing optimization. For example, the channel estimate and equalization coefficient based timing recovery can maximize a quality measure SNR_{symbol} defined as the signal-to-noise ratio of the decoded symbols.

Although embodiments of the present invention have been illustrated in the accompanied drawings and described in the foregoing detailed description, it will be understood that the invention is not limited to the embodiments disclosed, but is capable of numerous rearrangements, modifications, and substitutions without departing from the spirit of the invention as set forth and defined by the following claims. For example, the channel estimation can be performed via hardware and/or software using a processor such as a Reduced Instruction Set Computer (RISC) or a Digital Signal Processor (DSP). Further, although depicted in a particular manner, more than one of the modules can be utilized in the present invention and functionality provided by one module can be fully and/or partially provided by another one of the modules. Also, the transfer of information from one module to another module can be performed by a wired or a wireless connection.

What is claimed is:

1. A timing and equalization coefficient module, comprising:
a timing estimation module;
a first channel estimation module communicably coupled to the timing estimation module;
a second channel estimation module communicably coupled to the timing estimation module;
a conversion module communicably coupled to the timing estimation module, to the first channel estimation module and to the second channel estimation module; and
an equalization filter coefficient computation module communicably coupled to the timing estimation module and to the first channel estimation module;
the conversion module receives an analog signal and outputs two streams of 1/T rate sampled signal data, the first stream including a sample time to the first channel estimation module and the second stream including a delayed sample time to the second channel estimation module;
the first channel estimation module provides a first 1/T resolution Channel Impulse Response (CIR) estimate to the timing estimation module and the second channel estimation module provides a second 1/T resolution CIR estimate to the timing estimation module;
the equalization filter coefficient computation module receives the first 1/T resolution CIR estimate and determines coefficients for a 1/T rate equalization filter based on the first 1/T resolution CIR estimate, and sends the coefficients to the timing estimation module; and
the timing estimation module determines a timing offset control parameter which is received by the conversion module.

2. The timing and equalization coefficient module of claim 1, wherein the sample time for the first stream is at sample time=t and the sample time for the second stream is at a delayed sample time=t−Ω where t=tₒ+k/T for k=0,1,2,3, . . . n, where tₒ=the timing offset control parameter, and where Ω is small compared to T.

3. The timing and equalization coefficient module of claim 1, wherein the conversion module is at least one of:
a dual output 1/T rate analog-to-digital conversion module; and
a dual output 1/T rate interpolation filter conversion module.

4. The timing and equalization coefficient module of claim 1, wherein the conversion module further utilizes the timing offset control parameter when the two streams are output.

5. The timing and equalization coefficient module of claim 1, wherein the conversion module further outputs the first stream from the timing and equalization module.

6. The timing and equalization coefficient module of claim 1, wherein the equalization filter coefficient computation module outputs the coefficients from the timing and equalization module.

7. The timing and equalization coefficient module of claim 1, wherein the 1/T resolution CIR estimates include CIR_{t-Ω} and CIRₜ, and the 1/T resolution of these CIR estimates corresponds to a unit time lag being equal to T.

8. A timing and equalization coefficient module, comprising:
a timing estimation module that:
receives a first 1/T resolution Channel Impulse Response (CIR) estimate, a second 1/T resolution CIR estimate, and coefficients based on the first 1/T resolution CIR estimate;
determines a first vector as an absolute value of the first 1/T resolution CIR estimate and a second vector as an absolute value of the coefficients;
determines the maximums of the first vector and of the second vector;
determines a first complex scalar based on the received first 1/T resolution CIR estimate, the second 1/T resolution CIR estimate and the maximum of the first vector;
determines a second complex scalar based on the received coefficients based on the first 1/T resolution CIR estimate and the maximum of the second vector; and
determines a timing offset control parameter based on the first complex scalar and the second complex scalar.

9. The timing and equalization coefficient module of claim 8, wherein the timing estimation module receives the first complex scalar and the second complex scalar and determines a timing error detector based on the received first complex scalar and the second complex scalar.

10. The timing and equalization coefficient module of claim 9, wherein the timing estimation module determines a timing offset adjustment based on the timing error detector, a slope parameter and a bias parameter.

11. The timing and equalization coefficient module of claim 10, wherein the timing estimation module determines a timing offset update based on the timing offset adjustment.

12. The timing and equalization coefficient module of claim 11, wherein the timing estimation module determines the timing offset control parameter based on the timing offset update.

13. A timing and equalization coefficient module, comprising:
a timing estimation module;
a conversion module communicably coupled to the timing estimation module, wherein the conversion module receives an analog signal and outputs two streams of 1/T rate sampled signal data, one of the streams including a delayed sample time; and
an equalization filter coefficient computation module communicably coupled to the timing estimation module, wherein the equalization filter coefficient computation module receives a first 1/T resolution Channel Impulse Response (CIR) estimate and determines coefficients for a 1/T rate equalization filter based on the first 1/T resolution CIR estimate, and sends the coefficients to the timing estimation module that determines a timing offset control parameter which is received by the conversion module.

14. The timing and equalization coefficient module of claim 13, comprising a first channel estimation module communicably coupled to the timing estimation module.

15. The timing and equalization coefficient module of claim 14, comprising a second channel estimation module communicably coupled to the timing estimation module.

16. The timing and equalization coefficient module of claim 15, comprising a conversion module communicably coupled to the first channel estimation module and to the second channel estimation module.

17. The timing and equalization coefficient module of claim 16, comprising an equalization filter coefficient computation module communicably coupled to the first channel estimation module.

18. The timing and equalization coefficient module of claim 17, comprising the two streams of 1/T rate sampled signal data, the first stream including a sample time to the first channel estimation module and the second stream including the delayed sample time to the second channel estimation module

19. The timing and equalization coefficient module of claim 18, comprising the first channel estimation module that provides the first 1/T resolution CIR estimate to the timing estimation module and the second channel estimation module that provides the second 1/T resolution CIR estimate to the timing estimation module.

20. The timing and equalization coefficient module of claim 13, wherein the conversion module further utilizes the timing offset control parameter when the two streams are output.
